(19) United States
(12) Patent Application Publication
(10) Pub. No.: US 2014/0374608 A1
(43) Pub. Date: Dec. 25, 2014

(54) RADIATION DETECTION APPARATUS AND METHOD OF MANUFACTURING THE SAME

(71) Applicant: CANON KABUSHIKI KAISHA, Tokyo (JP)

(72) Inventors: Yoshito Sasaki, Kumagaya-shi (JP); Satoshi Okada, Tokyo (JP); Shoshiro Saruta, Kodama-gun (JP); Kazumi Nagano, Honjo-shi (JP); Yohei Ishida, Honjo-shi (JP)

(21) Appl. No.: 14/305,283

(22) Filed: Jun. 16, 2014

(30) Foreign Application Priority Data
Jun. 19, 2013 (JP) 2013-129032
Jun. 19, 2013 (JP) 2013-129033

(51) Int. Cl. H01L 31/18; H01L 27/146; H01L 31/0232

(52) U.S. Cl. CPC H01L 31/1876; H01L 31/02322; H01L 27/14625; H01L 31/1892; H01L 27/14685
USPC 250/366; 438/65; 257/428

(57) ABSTRACT

A method of manufacturing a radiation detection apparatus, includes a bonding step of bonding, on a support substrate, a sensor substrate including a photoelectric converter in which a plurality of photoelectric conversion elements are arranged, by using a bonding layer including a passage which exhausts a gas between the support substrate and the sensor substrate, and a formation step of forming a scintillator layer on the photoelectric converter after the bonding step. The bonding layer has a heat resistance by which bonding between the support substrate and the sensor substrate by the bonding layer is maintained in the formation step.

### BACKGROUND OF THE INVENTION

1. Field of the Invention

The present invention relates to a radiation detection apparatus and a method of manufacturing the same.

2. Description of the Related Art

A radiation detection apparatus in which a scintillator layer is arranged on a photoelectric conversion element array is known. Japanese Patent Laid-Open No. 2008-224429 describes a radiation detection apparatus in which a sensor panel including a substrate, a photoelectric conversion element array arranged on the substrate, and a scintillator layer arranged on the photoelectric conversion element array is adhered to a support member by an adhesive layer. The adhesive layer is formed by a resin layer having a porous structure.

There is a method by which a sensor substrate on which a photoelectric converter is arranged and a support substrate for supporting the sensor substrate are bonded by a bonding layer, and a scintillator layer is formed on the sensor substrate by a vapor-deposition method. When using a normal heat-resistant resin as the bonding layer in this method, peeling may occur in the interface between the sensor substrate and heat-resistant resin and/or the interface between the support substrate and heat-resistant resin during the formation of the scintillator layer. This is so because a bubble not exhausted from the interface between the sensor substrate and heat-resistant resin and/or the interface between the support substrate and heat-resistant resin when the sensor substrate and support substrate are bonded expands due to heat for vapor deposition or a pressure difference (a difference between the internal pressure of a vacuum chamber and the internal pressure of the bubble).

### SUMMARY OF THE INVENTION

The present invention provides a technique advantageous to form a scintillator layer on a sensor substrate by a vapor-deposition method after the sensor substrate and a support substrate are bonded by a bonding layer.

One of aspects of the present invention provides a method of manufacturing a radiation detection apparatus, the method comprising: a bonding step of bonding, on a support substrate, a sensor substrate including a photoelectric converter in which a plurality of photoelectric conversion elements are arranged, by using a bonding layer including a passage which exhausts a gas between the support substrate and the sensor substrate; and a formation step of forming a scintillator layer on the photoelectric converter after the bonding step, wherein the bonding layer has a heat resistance by which bonding between the support substrate and the sensor substrate by the bonding layer is maintained in the formation step.

Further features of the present invention will become apparent from the following description of exemplary embodiments with reference to the attached drawings.

### BRIEF DESCRIPTION OF THE DRAWINGS

FIGS. 1A and 1B are schematic plan views showing a radiation detection panel and a sensor panel as a constituent element thereof according to one embodiment of the present invention;

FIGS. 2A to 2C are partial schematic sectional views showing the radiation detection panel according to the embodiment of the present invention and a radiation detection apparatus incorporating the panel;

FIG. 3 is a schematic sectional view showing a modification of the radiation detection panel;

FIGS. 4A to 4C are views showing a method of manufacturing the radiation detection apparatus according to an embodiment of the present invention;

FIGS. 5A to 5C are views showing the method of manufacturing the radiation detection apparatus according to the embodiment of the present invention;

FIGS. 6A to 6C are views showing the method of manufacturing the radiation detection apparatus according to the embodiment of the present invention;

FIG. 7 is a view showing Examples 1 to 4 and Comparative Examples 1 and 2;

FIG. 8 is a view showing Examples 1 to 4 and Comparative Examples 1 and 2; and

FIG. 9 is a view exemplarily showing a radiation image sensing system.

### DESCRIPTION OF THE EMBODIMENTS

### First Embodiment

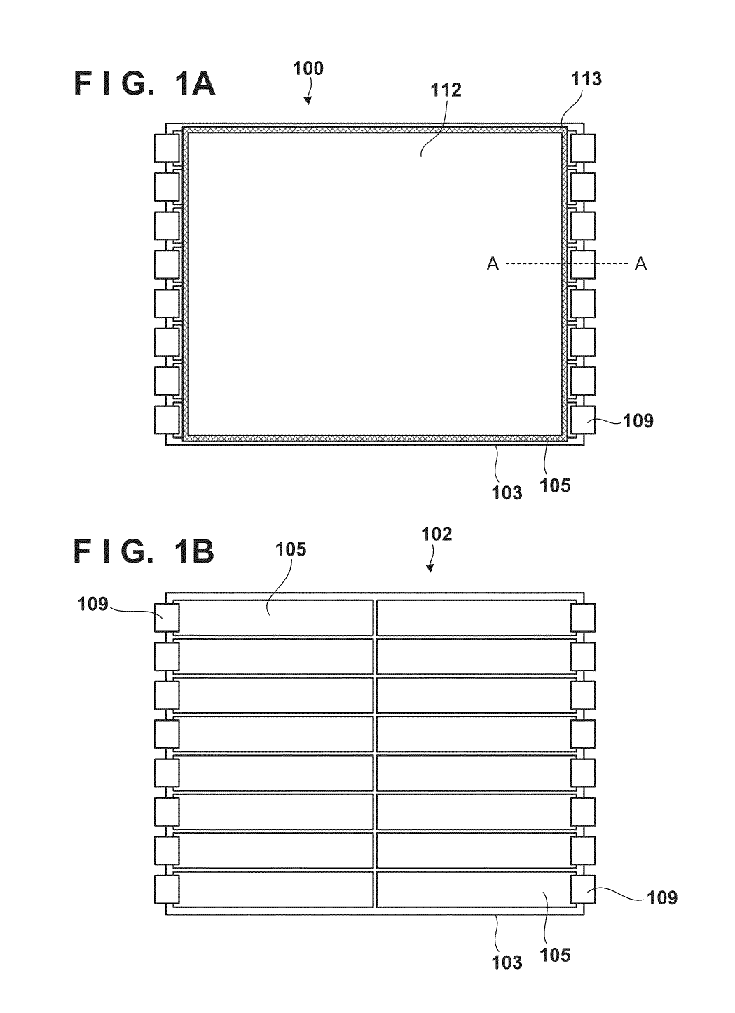

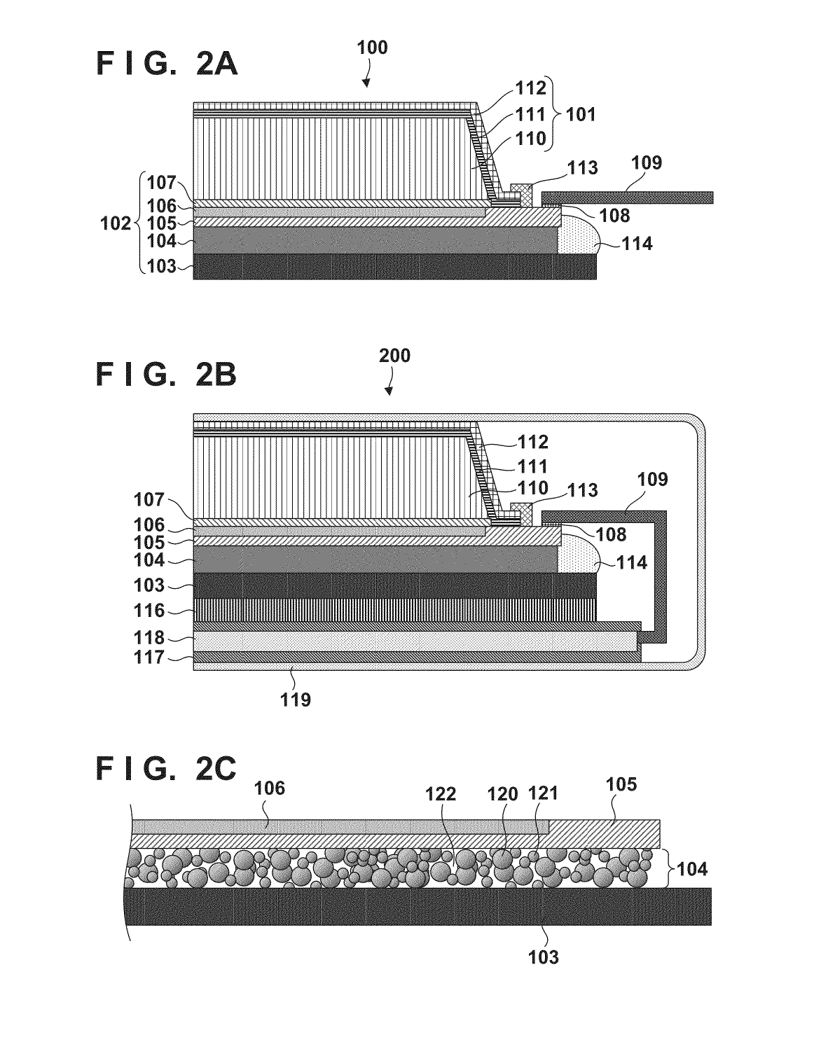

FIG. 1A is a schematic plan view of a radiation detection panel 100 according to one embodiment of the present invention. FIG. 1B shows a sensor panel 102 as a constituent element of the radiation detection panel 100. FIG. 2A is a sectional view of the radiation detection panel 100 taken along a line A-A in FIG. 1A. FIG. 2B is a sectional view showing a portion (corresponding to the portion shown in FIG. 2A) of a radiation detection apparatus 200 incorporating the radiation detection panel 100. FIG. 2C is an enlarged schematic view of the portion shown in FIG. 2A.

The radiation detection panel 100 includes a sensor panel 102, and a scintillator 101 bonded to the sensor panel 102. The sensor panel 102 includes a sensor substrate 105 on which a photoelectric converter 106 is formed, a support substrate 103, and a bonding layer 104 for bonding the support substrate 103 and sensor substrate 105. Also, the sensor panel 102 can include a protection layer 107 for protecting the photoelectric converter 106 formed on the sensor substrate 105, and a pad 108. The pad 108 is connected to a connecting portion 109 such as a flexible cable for connecting the sensor panel 102 and a mount board 118.

The scintillator 101 includes a scintillator layer 110 for converting radiation into light. The scintillator layer 110 can further include a protection layer 111 for protecting the scintillator layer 110 and/or a reflection layer 112. A sealing portion 113 which prevents water from entering the scintillator layer 110 is formed at the end portions of the protection layer 111 and reflection layer 112. A sealing portion 114 can also be formed at the end portion of the bonding layer 104.

Radiation is typically X-rays, but may also be α-rays, β-rays, or γ-rays. Radiation emitted from a radiation source and transmitted through an object is converted into light by the scintillator layer 110, the light is converted into charges by the photoelectric converter 106, and a signal corresponding to the charges is output from the sensor panel 102.

The radiation detection apparatus 200 includes a protection portion 117 for holding and protecting the mount board 118, a damper material 116 arranged between the support substrate 103 of the sensor panel 102 and the protection portion 117, and a housing 119 for accommodating these members. The mount board 118 includes circuits for controlling the sensor panel 102 and processing signals from the sensor panel 102, and is connected to the sensor panel 102 by the connecting portions 109.

The photoelectric converter 106 includes at least one photoelectric conversion element, and typically includes a photoelectric conversion element array including a plurality of photoelectric conversion elements. The sensor substrate 105 can be, for example, a semiconductor substrate such as a silicon substrate. When the sensor substrate 105 is a semiconductor substrate, the photoelectric conversion elements forming the photoelectric converter 106 can be formed in this semiconductor substrate. The sensor substrate 105 can include a switching element for reading out charges generated by the photoelectric conversion elements.

As exemplarily shown in FIG. 1B, one surface of one support substrate 103 can support a plurality of sensor substrates 105. However, it is also possible to support one sensor substrate 105 by one surface of one support substrate 103. An arrangement in which one support substrate 103 supports a plurality of sensor substrates 105, that is, an arrangement in which a plurality of sensor substrates 105 are tiled is advantageous to obtain a radiation detection apparatus having a large image sensing region.

Details of each portion of the radiation detection apparatus 200 will exemplarily be explained below.

The protection layer 107 can be made of, for example, SiN, TiO₂, LiF, Al₂O₃, or MgO. The protection layer 107 can also be made of a polyphenylene sulfide resin, fluorine resin, polyether ether ketone resin, liquid crystal polymer, polyether nitrile resin, polysulfone resin, polyether sulfone resin, or polyarylate resin. Alternatively, the protection layer 107 can be made of a polyamidoimide resin, polyetherimide resin, polyimide resin, epoxy resin, or silicone resin. However, the protection layer 107 must be made of a material having a high transmittance to the wavelength of light converted by the scintillator layer 110, so that the light converted by the scintillator layer 110 can pass through the protection layer 107.

The support substrate 103 can be made of a material having a high heat resistance. More specifically, the support substrate 103 can be made of glass, silicon, Si₃N₄, AlN, or molybdenum. Alternatively, the support substrate 103 can be made of CFRP, GFRP, AFRP, or amorphous carbon.

As schematically shown in FIG. 2C, the bonding layer 104 contains particles 120 and an adhesive agent 121, and the particles 120 are so arranged as to form a cavity 122 between them. Also, the bonding layer 104 has a heat resistance by which the bonding between the sensor substrate 105 and support substrate 103 by the bonding layer 104 is maintained in the step of forming the scintillator layer 110 on the sensor substrate 105 by a vapor-deposition method. For example, the bonding layer 104 preferably has a heat resistance by which the bonding between the sensor substrate 105 and support substrate 103 is maintained at a temperature of 200° C. or more. The bonding layer 104 is formed by curing the bonding material. The bonding material of course contains the particles 120 and adhesive agent 121 as the constituent elements of the bonding layer 104.

The particles 120 may be particles made of an organic material, particles made of an inorganic material, or particles made of an organic material and inorganic material. The adhesive agent 121 bonds the particles 120 to each other. The adhesive agent 121 also bonds the particles 120 and sensor substrate 105, and the particles 120 and support substrate 103. The adhesive agent 121 may be made of an organic material, an inorganic material, or an organic material and inorganic material.

When bonding the sensor substrate 105 and support substrate 103 by the bonding layer 104, a gas may be confined in the interface between the sensor substrate 105 and bonding layer 104 and/or the interface between the support substrate 103 and bonding layer 104, thereby forming a bubble. If there is no passage for exhausting this gas, the bubble may expand due to heat for vapor deposition or a pressure difference (a difference between the internal pressure of a vacuum chamber and the internal pressure of the bubble) when forming the scintillator layer 110 on the sensor substrate 105 by a vapor-deposition method. In this embodiment, the cavity 122 existing between the particles 120 provides a gas passage. This suppresses peeling caused by the expansion of the bubble in the interface between the sensor substrate 105 and bonding layer 104 and/or the interface between the support substrate 103 and bonding layer 104.

When forming the particles 120 by an organic material, the material of the particles 120 is preferably at least one material selected from the following group.

<A Methyl Polymethacrylate-Based Crosslinked Material, Butyl Polymethacrylate-Based Crosslinked Material, Polyacrylic Ester Crosslinking Material, Styrene-Acrylic-Based Crosslinking Material, Polyamidoimide Resin, Polyphenylene Sulfide Resin, Epoxy Resin, and Polyether Sulfone Resin>

When forming the particles 120 by an inorganic material, the material of the particles 120 is preferably at least one material selected from the following group.

<Silica, Alumina, Cordierite, Bentonite, Zirconia, Zircon, Carbon, Yttrium Oxide, Magnesia, Titania, and Chromium Oxide>

When forming the particles 120 by an organic material and inorganic material, the material of the particles 120 is preferably a silica-acryl composite compound as a composite material of an organic material and inorganic material.

As the adhesive agent 121, an epoxy-based, acrylic-based, or silicone-based adhesive agent is favorable as an organic material, and alkali metal silicate-based, phosphate-based, or silica sol-based adhesive agent is favorable as an inorganic material.

The bonding material for forming the bonding layer 104 can be applied by, for example, a spray, a slit coater, screen printing, a spin coater, a bar coater, a doctor blade, dipping, wash coating, a marking device, a dispenser, a brush, or a paintbrush. The thickness of the bonding layer 104 is preferably 20 μm or more. This is so because when tiling a plurality of sensor substrates 105, a maximum thickness variation between the sensor substrates 105 can be 20 μm. The upper limit of the thickness of the bonding layer 104 is not particularly defined, and can freely be determined in accordance with the specifications.

Since the maximum thickness variation between the sensor substrates 105 can be 20 μm, the diameter of the particles 120 is preferably 20 μm or less in order to bury steps between the sensor substrates 105. Also, if the diameter of the particles 120 is excessively decreased, it is impossible to secure a sufficient passage for exhausting a gas confined when bonding the sensor substrates 105 and support substrate 103. Therefore, the diameter of the particles 120 is preferably 0.1 μm or more.

The volumetric filling factor of the particles 120 in the bonding layer 104 is preferably 40% (inclusive) to 80% (inclusive). If the volumetric filling factor is lower than 40%, the strength of the bonding layer 104 decreases. If the volumetric filling factor is higher than 80%, it is impossible to secure a sufficient passage for exhausting a gas.

From the viewpoints of the dispersibility of the bonding material to an organic solvent (for example, alcohol), the bonding strength, and the insurance of the cavity 122, a value calculated by expression (1) below is preferably 0.01% (inclusive) to 10% (inclusive).

(Volume of all organic adhesive agents contained in bonding material)/(volume of all particles 120 contained in bonding material)+(volume of all organic adhesive agents contained in bonding material)+(volume of all inorganic adhesive agents contained in bonding material) (1)

The scintillator layer 110 can have an area smaller than that of a sensor substrate array including a plurality of tiled sensor substrates 105. The scintillator layer 110 can be, for example, a columnar crystal scintillator represented by cesium iodide (CsI:Tl) to which a very small amount of thallium (Tl) is added. Alternatively, the scintillator layer 110 can be made of a granular scintillator represented by gadolinium oxysulfide (GOS:Tb) to which a very small amount of terbium (Tb) is added.

The protection layer 111 is arranged on the scintillator layer 110. The protection layer 111 is so arranged as to cover the whole or a part of the scintillator layer 110. Especially when the scintillator layer 110 is made of a columnar crystal scintillator such as CsI:Tl, the characteristics of the scintillator layer 110 deteriorate due to water, so the protection layer 111 is necessary. The thickness of the protection layer 111 is preferably 20 μm (inclusive) to 200 μm (inclusive). If the thickness is less than 20 μm, it is difficult to completely cover the roughness and a defect caused by abnormal growth on the surface of the scintillator layer 110, so a moistureproofing function may deteriorate. On the other hand, if the thickness exceeds 200 μm, the scattering of light generated in the scintillator layer 110 or light reflected by the reflection layer 112 increases in the protection layer 111, so the resolution and MTF (Modulation Transfer Function) of an obtained image may decrease.

Examples of the material of the protection layer 111 are general organic sealing materials such as a silicone resin, acrylic resin, and epoxy resin, and polyester-based, polyolefin-based, and polyamide-based hot-melt resins, and a resin having a low water permeability is particularly desirable. As the protection layer 111, an organic film such as polyparaxylylene, polyurea, or polyurethane formed by CVD is suitable. Furthermore, a hot-melt resin can also be adopted as long as the resin can resist the heating step during the manufacture. Examples of the hot-melt resin satisfying the moistureproofness required of the protection layer 111 are a polyolefin-based resin and polyester-based resin. A polyolefin resin is particularly suitable as a resin having a low moisture absorption coefficient. The polyolefin-based resin is also suitable as a resin having a high light transmittance. Accordingly, a hot-melt resin containing a polyolefin-based resin as a base material is more favorable as the protection layer 111.

The polyolefin resin can contain, as a main component, at least one of an ethylene-vinyl acetate copolymer, ethylene-acrylic acid copolymer, ethylene-acrylic ester copolymer, ethylene-methacrylic acid copolymer, and ethylene-methacrylic ester copolymer. Alternatively, the polyolefin resin can contain an ionomer resin as a main component.

As the hot melt, it is possible to use, for example, Hirodine 7544 (manufactured by Hirodine), O-4121 (manufactured by KURABO), W-4210 (manufactured by KURABO), H-2500 (manufactured by KURABO), P-2200 (manufactured by KURABO), Z-2 (manufactured by KURABO), or M-5 (manufactured by KURABO).

Of light converted from radiation by the scintillator layer 110, the reflection layer 112 reflects light propagating to the side opposite to the photoelectric converter 106, and guides the light to the photoelectric converter 106, thereby increasing the light utilization efficiency. Also, the reflection layer 112 prevents light (external light) other than the light generated by the scintillator layer 110 from entering the photoelectric converter 106.

The reflection layer 112 is preferably a metal foil, metallic thin film, or the like. The thickness of the reflection layer 112 is preferably 1 μm (inclusive) to 100 μm (inclusive). If the thickness is less than 1 μm, a pinhole defect readily occurs during the formation of the reflection layer 112, and the light shielding properties deteriorate. On the other hand, if the thickness exceeds 100 μm, the radiation absorption amount increases too much, and the size of a step formed on the sensor substrate 105 by the end portion of the reflection layer 112 increases too much. Examples of the material of the reflection layer 112 are metal materials such as aluminum, gold, copper, and an aluminum alloy. Of these materials, aluminum or gold as a material having a high reflectance is particularly favorable.

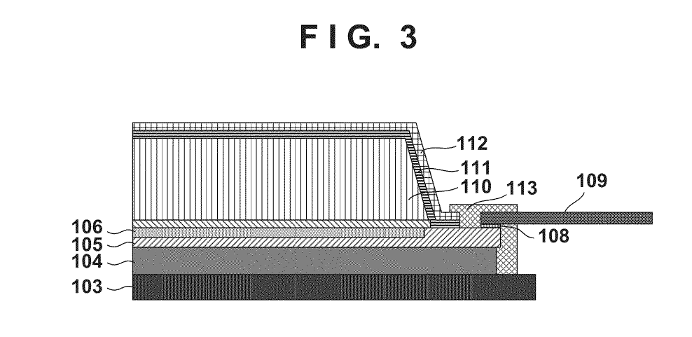

The sealing portions 113 and 114 are preferably made of a material having a high moistureproofness and a low water permeability, for example, an epoxy-based resin or acrylic-based resin. The sealing portions 113 and 114 may also be made of a silicone-based, polyester-based, polyolefin-based, or polyamide-based resin. When the sealing portions 113 and 114 are made of a thermosetting resin, a resin which sets with heat lower than the heat-resistant temperature of the connecting portions 109 is favorable. However, when forming the sealing portion 113 before connecting the connecting portions 109 to the pads 108, the sealing portion 113 may also be formed by a sealing resin having a setting temperature of 200° C. or less. Furthermore, the sealing portions 113 and 114 may be made of a resin other than the thermosetting resin, for example, a UV-curing resin, two-component-curing resin, or air-setting resin. The sealing portions 113 and 114 may be made of the same material or different materials. As exemplarily shown in FIG. 3, the sealing portion 113 may also function as the sealing portion 114.

The protection portion 117 for holding and protecting the mount board 118 can be made of Al, stainless steel, Mg, Cu, Zn, Sn, Zn, an oxide or alloy thereof, amorphous carbon, carbon-fiber-reinforced material, or a resin molded product containing an organic polymer. The housing 119 is preferably formed by the same material as that of the protection portion 117 for holding and protecting the mount board 118.

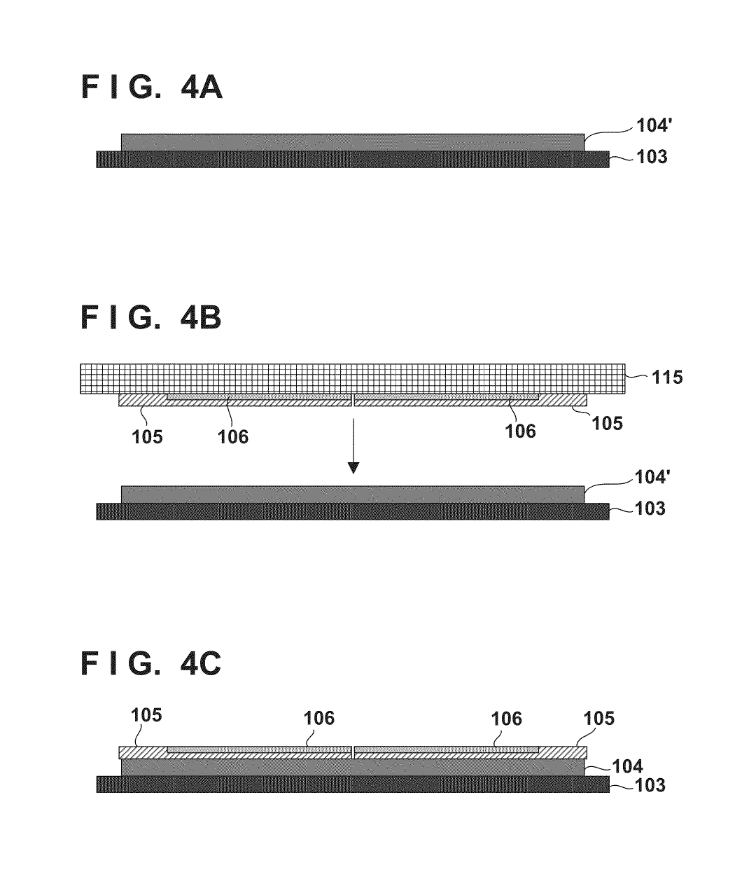

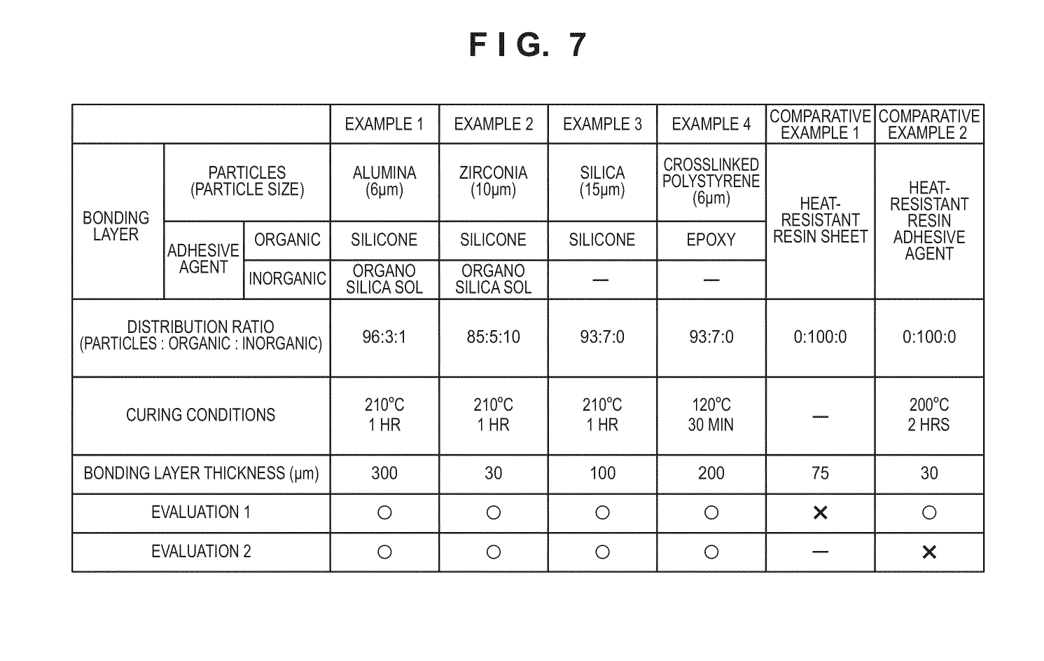

Practical Examples 1 to 4 of a method of manufacturing the radiation detection apparatus 200 and Comparative Examples 1 and 2 will be explained below with reference to FIGS. 4A to 4C, 5A to 5C, and 6A to 6C. Examples 1 to 4 and Comparative Examples 1 and 2 are summarized in FIG. 7.

### Example 1

First, in a step shown in FIG. 4A, the surface of a support substrate 103 is coated with a bonding material 104′ by screen printing. The bonding material 104′ used in this step is formed by dispersing inorganic particles made of alumina, a silicone resin (inorganic adhesive agent), and an organo silica sol (organic adhesive agent) in alcohol (an organic solvent). The volume distribution ratio of the inorganic particles, silicone resin, and organo silica sol can be inorganic particles:silicone resin:silica sol=96:3:1.

In a step shown in FIG. 4B, a plurality of sensor substrates 105 arranged by a tiling device are chucked by an chucking jig 115, and brought into contact with the bonding material 104′ on the support substrate 103 in this state.

In a step shown in FIG. 4C, while the chucking jig 115 is chucking the plurality of sensor substrates 105, the bonding material 104′ is heated at 210° C. for 1 hr. Consequently, the bonding material 104′ cures and forms a bonding layer 104. In this step, a cavity 122 is formed between particles 120.

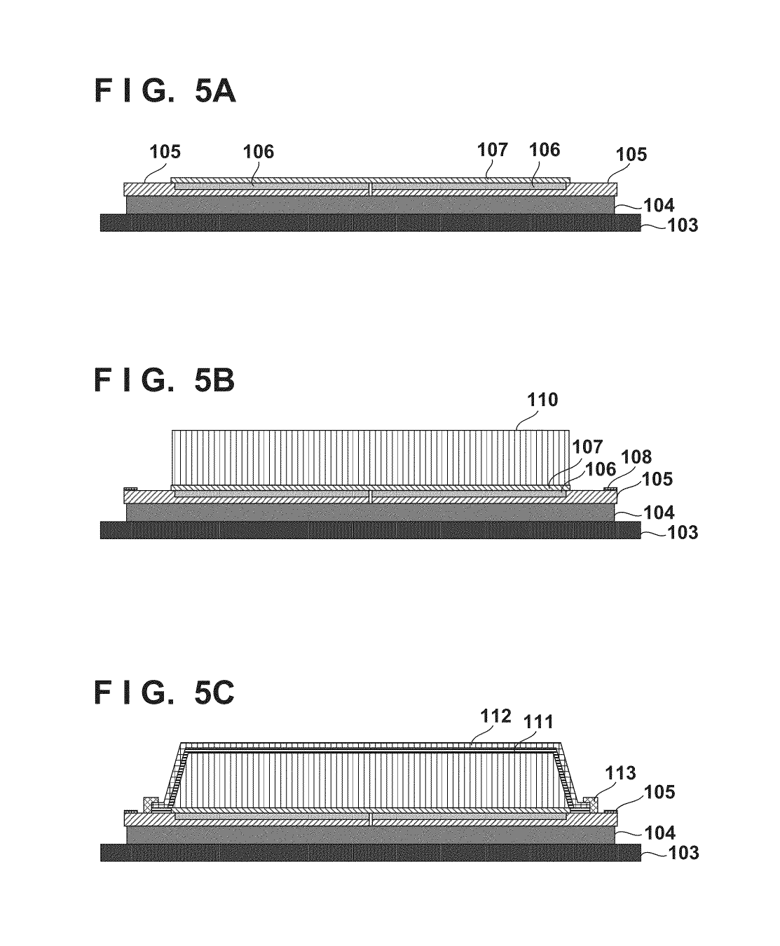

In a step shown in FIG. 5A, a protection layer 107 is formed by coating the sensor substrates 105 with a protection film material made of polyimide, and curing the material at 200° C.

In a step shown in FIG. 5B, a scintillator layer 110 having a columnar crystal structure is formed on the protection layer 107. When forming the scintillator layer 110 by using CsI:Tl, the scintillator layer 110 can be formed by codeposition of CsI (cesium iodide) and TlI (thallium iodide). More specifically, the material of the scintillator layer 110 is filled as a deposition material in a resistance-heating boat, a sensor panel 102 on which the protection layer 107 is formed is placed in a rotatable holder installed inside a vapor-deposition apparatus. Then, while the vapor-deposition apparatus is evacuated, the vacuum degree is adjusted by supplying argon (Ar) gas, and the temperature is raised to a maximum of 200° C., thereby forming the scintillator layer 110 on the sensor panel 102.

In a step shown in FIG. 5C, a film-like sheet obtained by stacking a reflection layer 112 made of an Al film on a protection layer made of PET is prepared. Then, a protection layer 111 made of a hot-melt resin, containing a polyolefin resin as a material, is adhered to the reflection layer 112 of the film-like sheet by using a heat roller. Consequently, a sheet having a three-layer structure is formed. After that, the sheet is so arranged as to cover the scintillator layer 110. Subsequently, the sheet is heated and pressed by a vacuum laminator, and fixed to the scintillator 110 and sensor panel 102 by welding the protection layer 111. After that, the peripheral portion is sealed by a sealing portion 113. Pads 108 can be formed after that.

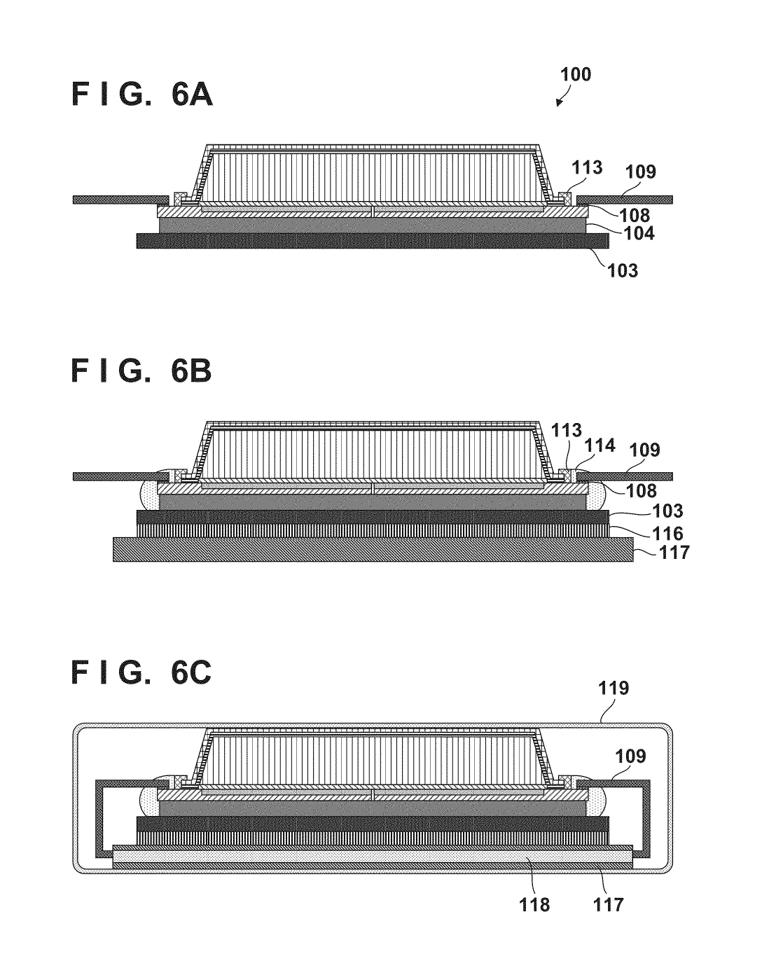

In a step shown in FIG. 6A, connecting portions 109 are connected to the pads 108 of the sensor substrates 105 by thermocompression bonding, thereby forming a radiation detection panel 100. In a step shown in FIG. 6B, the radiation detection panel 100 is adhered to a protection portion 117 via a damper material 116. In a step shown in FIG. 6C, the connecting portions 109 are connected to a mount board 118, and the structure including the radiation detection panel 100, damper material 116, and protection portion 117 is covered with a housing 119.

A radiation detection apparatus 200 was manufactured in accordance with the above-described manufacturing method, and evaluated as follows.

(Evaluation 1)

Immediately after the scintillator layer was vapor-deposited, the sensor panel 102 was visually inspected. In this inspection, a bonding defect caused between the sensor substrate 105 and support substrate 103 by the expansion of a bubble and a positional shift of the sensor substrate 105 from the support substrate 103 were checked.

(Evaluation 2)

An image output from the radiation detection apparatus 200 was evaluated by irradiating the radiation detection apparatus 200 with radiation.

As a result of the evaluations, no trouble was confirmed.

### Example 2

In the step shown in FIG. 4A, the surface of a support substrate 103 is coated with a bonding material 104′ by screen printing. The bonding material 104′ used in this step is formed by dispersing inorganic particles made of zirconia, a silicone resin (inorganic adhesive agent), and an organo silica sol (organic adhesive agent) in alcohol (an organic solvent). The volume distribution ratio of the inorganic particles, silicone resin, and silica sol inorganic particles can be inorganic particles:silicone resin:silica sol=85:5:10. Steps after that are the same as in Example 1.

The same evaluations as in Example 1 were performed, and no trouble was confirmed.

### Example 3

In the step shown in FIG. 4A, the surface of a support substrate 103 is coated with a bonding material 104′ by screen printing. The bonding material 104′ used in this step is formed by dispersing inorganic particles made of silica and a silicone resin (inorganic adhesive agent) in alcohol (an organic solvent). The volume distribution ratio of the inorganic particles and silicone resin can be inorganic particles:silicone resin=93:7. Steps after that are the same as in Example 1.

The same evaluations as in Example 1 were performed, and no trouble was confirmed.

### Example 4

In the step shown in FIG. 4A, the surface of a support substrate 103 is coated with a bonding material 104′ by screen printing. The bonding material 104′ used in this step is formed by organic particles made of a crosslinked polystyrene resin and an epoxy resin (organic adhesive agent). The volume distribution ratio of the organic particles and epoxy resin can be crosslinked polystyrene:epoxy resin=93:7.

In the step shown in FIG. 4B, a plurality of sensor substrates 105 arranged by a tiling device are chucked by an chucking jig 115, and brought into contact with the bonding material 104′ on the support substrate 103 in this state. That is, in the step shown in FIG. 4B, the sensor substrates 105 and support substrate 103 are arranged with the bonding material 104′ being sandwiched between them.

In the step shown in FIG. 4C, while the chucking jig 115 is chucking the plurality of sensor substrates 105, the bonding material 104′ is heated at 120° C. for 30 min. Consequently, the bonding material 104′ cures and forms a bonding layer 104. In this step, a cavity 122 is formed between particles 120. Steps after that are the same as in Example 1.

The same evaluations as in Example 1 were performed, and no trouble was confirmed.

### Comparative Example 1

In the same procedures as in Example 1, a heat-resistant silicone-based adhesive sheet was used as an adhesive layer for adhering a support substrate 103 and sensor substrates 105.

When (evaluation 1) was performed, peeling of the sensor substrate 105 occurred due to a bubble, so (evaluation 2) was not performed.

### Comparative Example 2

In the same procedures as in Example 1, a heat-resistant polyimide-based adhesive sheet was used as an adhesive layer for adhering a support substrate 103 and sensor substrates 105.

When (evaluation 1) was performed, no trouble was confirmed. When (evaluation 2) was performed, however, incongruity occurred in an image output from a radiation detection apparatus 200.

### Second Embodiment

As described previously, Japanese Patent Laid-Open No. 2008-224429 describes a radiation detection apparatus in which a sensor panel including a substrate, a photoelectric conversion element array arranged on the substrate, and a scintillator layer arranged on the photoelectric conversion element array is adhered to a support member by an adhesive layer. The adhesive layer is formed by a resin layer having a porous structure.

The thermal expansion coefficient of the resin layer is much higher than that of the substrate on which a photoelectric converter such as the photoelectric conversion element array is arranged. Therefore, if high heat is applied to the resin layer after the substrate is adhered to the support member by the resin layer, a large stress may be applied to the substrate. This may break the substrate or shift the position of the substrate. Especially in a large-screen radiation detection apparatus in which a plurality of substrates are supported by one support substrate, the relative positional shifts of the plurality of substrates have a large influence on the quality of an output image from the radiation detection apparatus.

It is an object of the second embodiment of the present invention to provide a technique advantageous to reduce a stress to be applied to a substrate on which a photoelectric converter is arranged.

The second embodiment of the present invention is directed to a method of manufacturing a radiation detection apparatus, and this manufacturing method includes a step of adhering a sensor substrate on which a photoelectric converter is formed to a support substrate by using an inorganic adhesive agent, and a step of forming a scintillator layer on the sensor substrate.

In the following description, differences from the first embodiment will be explained. Items not mentioned below can follow those of the first embodiment.

A support substrate 103 can be made of a material having a high heat resistance and a small thermal expansion coefficient (for example, 10×10⁻⁶ K⁻¹ or less). More specifically, the support substrate 103 can be made of glass, silicon, Si₃N₄, AlN, or molybdenum. Alternatively, the support substrate 103 can be made of CFRP, GFRP, AFRP, or amorphous carbon.

A bonding layer 104 can be made of an inorganic adhesive agent. High heat is applied to the bonding layer 104 when a scintillator layer 110 is formed on a sensor substrate 105 by a vapor-deposition method after the sensor substrate 105 and support substrate 103 are adhered by an inorganic adhesive agent (the constituent material of the bonding layer 104). In this case, therefore, the bonding layer 104 must be made of a material which can resist heat for forming the scintillator layer 110.

Also, if the thermal expansion coefficient of the bonding layer 104 is large, a large stress can be applied to the sensor substrate 105 when heat is applied to the bonding layer 104 and sensor substrate 105. This may break the sensor substrate 105 or shift the position of the sensor substrate 105. Especially when a plurality of sensor substrates 105 are arranged, the positional shifts of the sensor substrates 105 may deteriorate the quality of an output image from a radiation detection apparatus 200. The thermal expansion coefficient of the bonding layer 104 (that is, a cured inorganic adhesive agent layer) is preferably, for example, 15×10⁻⁶ K⁻¹ or less. Especially when the sensor substrate 105 is made of silicon (thermal expansion coefficient: 2.6×10⁻⁶ K⁻¹) and the support substrate 103 is made of CFRP (thermal expansion coefficient: 0.1×10⁻⁶ K⁻¹), the thermal expansion coefficient of the bonding layer 104 is preferably 15×10⁻⁶ K⁻¹ or less.

The inorganic adhesive agent forming the bonding layer 104 has a heat resistance by which the bonding between the support substrate 103 and sensor substrate 105 by the bonding layer 104 is maintained in a step shown in FIG. 5B, that is, in a step of forming the scintillator layer 110 on a protection layer 107 (photoelectric converter 106). The inorganic adhesive agent forming the bonding layer 104 is preferably, for example, an alkali metal silicate-based, phosphate-based, or silica sol-based adhesive agent. An inorganic filler (filling agent) and/or hardener may also be added to the inorganic adhesive agent. The filler can contain at least one type of particles made of, for example, silica, alumina, cordierite, bentonite, zirconia, zircon, carbon, phosphoric acid, yttrium oxide, magnesia, titania, and chromium oxide.

When using the silica sol-based adhesive agent as the inorganic adhesive agent, a proper amount of colloidal silica is added to an aqueous solution in which inorganic particles are dissolved while the aqueous solution is stirred. After that, the supernatant liquid except for the precipitate is removed, and the precipitate is dried at 100° C. An aqueous solution is prepared by adding water to the dried precipitate, and colloidal silica is added to the aqueous solution. By repeating this process, it is possible to obtain an adhesive agent with which colloidal silica is adsorbed on the surfaces of the inorganic particles.

The inorganic adhesive agent can be applied by, for example, a spray, a bar coater, a doctor blade, dipping, wash coating, a marking device, a dispenser, a brush, or a paintbrush.

In a radiation detection panel 100 or the radiation detection apparatus 200 of the second embodiment, a positional shift of the sensor substrate 105 caused by heat is prevented during or after the manufacture.

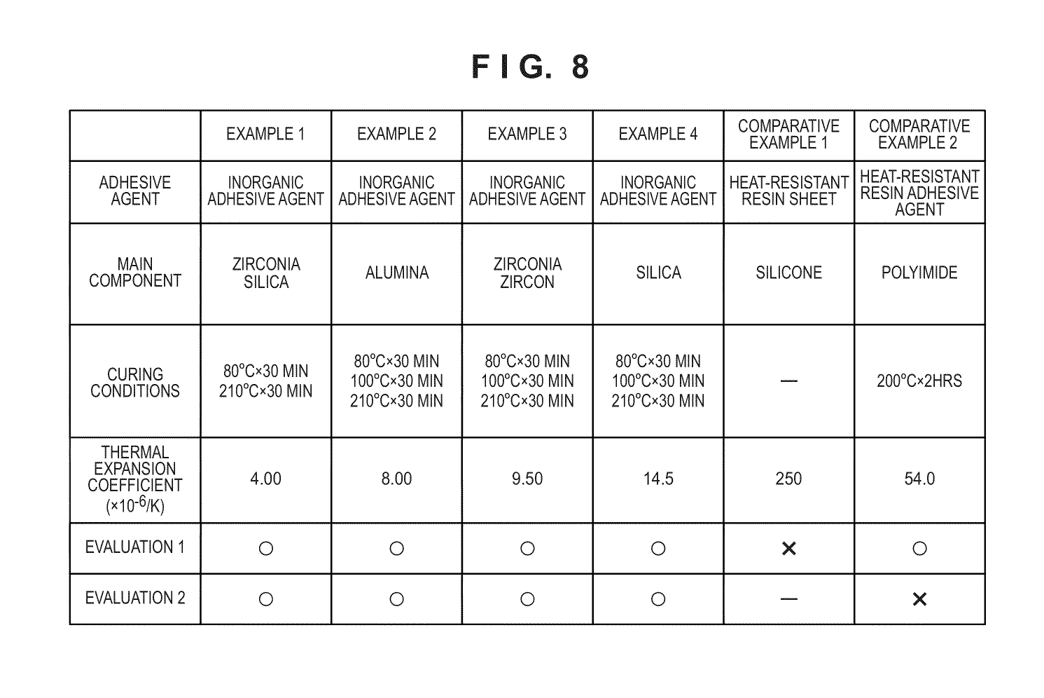

Practical Examples 1 to 4 of a method of manufacturing the radiation detection apparatus 200 and Comparative Examples 1 and 2 will be explained below with reference to FIGS. 4A to 4C, 5A to 5C, and 6A to 6C. Examples 1 to 4 and Comparative Examples 1 and 2 are summarized in FIG. 8.

### Example 1

First, in a step shown in FIG. 4A, the surface of a support substrate 103 is treated by a plasma, and coated with an inorganic adhesive agent 104′ containing colloidal silica, silica microparticles as inorganic particles, and zirconia microparticles by a spray. The support substrate 103 is made of CFRP (thermal expansion coefficient: 0.1×10⁻⁶ K⁻¹).

In a step shown in FIG. 4B, a plurality of sensor substrates 105 arranged by a tiling device are chucked by an chucking jig 115, and adhered to the support substrate 103 by the inorganic adhesive agent 104′ in this state. The sensor substrate 105 is a silicon substrate (thermal expansion coefficient: 2.6×10⁻⁶ K⁻¹).

In a step shown in FIG. 4C, while the chucking jig 115 is chucking the plurality of sensor substrates 105, the inorganic adhesive agent 104′ is heated at 80° C. for 30 min. In addition, the inorganic adhesive agent 104′ is heated at 210° C. for 30 min in a state in which the chucking is canceled. Consequently, the inorganic adhesive agent 104′ cures and forms a bonding layer 104.

In a step shown in FIG. 5A, a protection layer 107 is formed by coating the sensor substrates 105 with a protection film material made of polyimide, and curing the material at 200° C.

In a step shown in FIG. 5B, a scintillator layer 110 having a columnar crystal structure is formed on the protection layer 107. When forming the scintillator layer 110 by using CsI:Tl, the scintillator layer 110 can be formed by codeposition of CsI (cesium iodide) and TlI (thallium iodide). More specifically, the material of the scintillator layer 110 is filled as a deposition material in a resistance-heating boat, and a sensor panel 102 on which the protection layer 107 is formed is placed in a rotatable holder installed inside a vapor-deposition apparatus. Then, while the vapor-deposition apparatus is evacuated, the vacuum degree is adjusted by supplying argon (Ar) gas, and the temperature is raised to a maximum of 200° C., thereby forming the scintillator layer 110 on the sensor panel 102. After that, pads 108 can be formed.

In a step shown in FIG. 5C, a film-like sheet obtained by stacking a reflection layer 112 made of an Al film on a protection layer made of PET is prepared. Then, a protection layer 111 made of a hot-melt resin containing a polyolefin resin as a material is adhered on the reflection layer 112 of the film-like sheet by using a heat roller. Consequently, a sheet having a three-layer structure is formed. After that, the sheet is so arranged as to cover the scintillator layer 110. Subsequently, the sheet is heated and pressed by a vacuum laminator, and fixed to the scintillator 110 and sensor panel 102 by welding the protection layer 111. After that, the peripheral portion is sealed by a sealing portion 113.

In a step shown in FIG. 6A, connecting portions 109 are connected to the pads 108 of the sensor substrates 105 by thermocompression bonding, thereby forming a radiation detection panel 100. In a step shown in FIG. 6B, the radiation detection panel 100 is adhered to a protection portion 117 via a damper material 116. In a step shown in FIG. 6C, the connecting portions 109 are connected to a mount board 118, and the structure including the radiation detection panel 100, damper material 116, and protection portion 117 is covered with a housing 119.

A radiation detection apparatus 200 was manufactured in accordance with the above-described manufacturing method, and evaluated as follows.

(Evaluation 1)

Immediately after the scintillator layer was vapor-deposited, the sensor panel 102 was visually inspected. In this inspection, a bonding defect caused between the sensor substrate 105 and support substrate 103 by the expansion of a bubble and a positional shift of the sensor substrate 105 from the support substrate 103 were checked.

(Evaluation 2)

An image output from the radiation detection apparatus 200 was evaluated by irradiating the radiation detection apparatus 200 with radiation. As a result of the evaluations, no trouble was confirmed.

### Example 2

In the step shown in FIG. 4A, an inorganic adhesive agent 104′ containing colloidal silica and alumina microparticles as inorganic particles is applied by a spray.

In the step shown in FIG. 4B, a plurality of sensor substrates 105 arranged by a tiling device are chucked by an chucking jig 115, and adhered to a support substrate 103 by the inorganic adhesive agent 104′ in this state.

In the step shown in FIG. 4C, while the chucking jig 115 is chucking the plurality of sensor substrates 105, the inorganic adhesive agent 104′ is heated at 80° C. for 30 min. In addition, in a state in which the chucking is canceled, the inorganic adhesive agent 104′ is heated at 100° C. for 30 min, and then heated at 210° C. for 30 min. Consequently, the inorganic adhesive agent 104′ cures and forms a bonding layer 104. Steps after that are the same as in Example 1.

The same evaluations as in Example 1 were performed, and no trouble was confirmed.

### Example 3

In the step shown in FIG. 4A, an inorganic adhesive agent 104′ containing colloidal silica and zirconia microparticles and zircon microparticles as inorganic particles is applied by a spray. Steps after that are the same as in Example 2.

The same evaluations as in Example 1 were performed, and no trouble was confirmed.

### Example 4

In the step shown in FIG. 4A, an inorganic adhesive agent 104′ containing colloidal silica and silica microparticles as inorganic particles is applied by a spray.

Steps after that are the same as in Example 2.

### Comparative Example 1

In the same procedures as in Example 1, a heat-resistant silicone-based adhesive sheet having a thermal expansion coefficient of 250×10⁻⁶ K⁻¹ was used as an adhesive layer for adhering a support substrate 103 and sensor substrates 105.

When (evaluation 1) was performed, a positional shift of the sensor substrate 105 was confirmed, so (evaluation 2) was not performed.

### Comparative Example 2

In the same procedures as in Example 1, a heat-resistant polyimide-based adhesive agent having a thermal expansion coefficient of 54×10⁻⁶ K⁻¹ was used as an adhesive layer for adhering a support substrate 103 and sensor substrates 105.

When (evaluation 1) was performed, no positional shift of the sensor substrate 105 was confirmed. When (evaluation 2) was performed, however, incongruity occurred in an image output from a radiation detection apparatus 200.

[Radiation Image Sensing System]

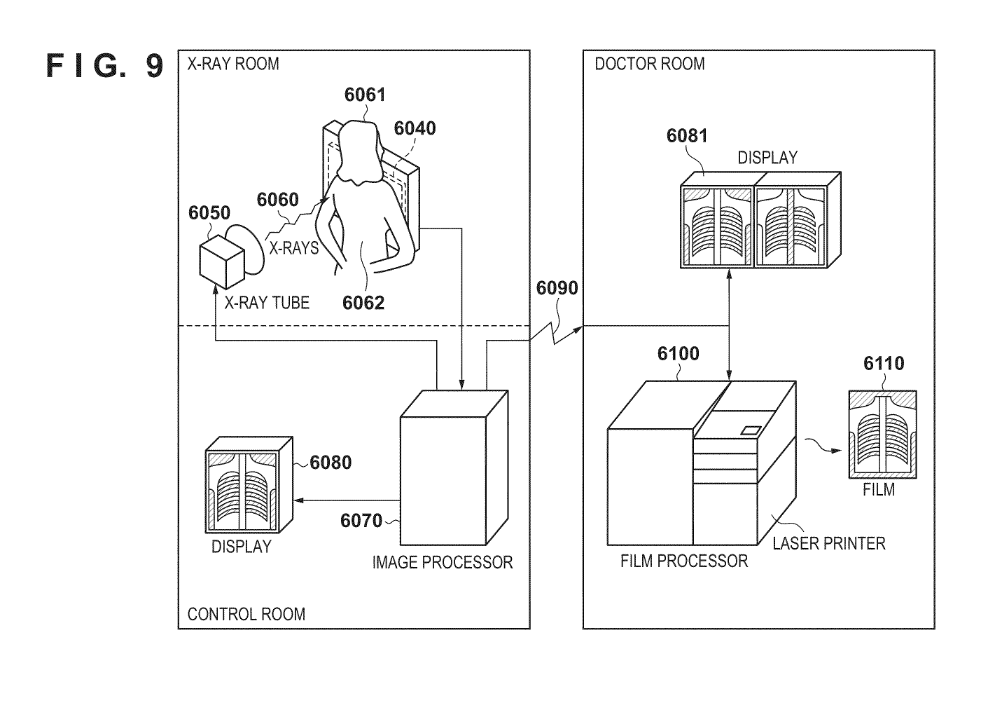

FIG. 9 is a view showing an example in which a solid-state image sensing device according to the present invention is applied to an X-ray diagnostic system (radiation image sensing system). This radiation image sensing system includes a radiation image sensing device 6040, and an image processor 6070 for processing a signal output from the radiation image sensing device 6040. The radiation image sensing device 6040 is obtained by configuring the above-described solid-state image sensing device 100 as a device for sensing an image of radiation as exemplarily shown in FIG. 1B. X-rays 6060 generated by an X-ray tube (radiation source) 6050 are transmitted through a chest 6062 of a patient or object 6061, and enter the radiation image sensing device 6040. The incident X-rays contain information about the interior of the body of the object 6061. The image processor (processor) 6070 processes a signal (image) output from the radiation image sensing device 6040, and, for example, can display an image on a display 6080 in a control room based on the signal obtained by the processing.

The image processor 6070 can also transfer the signal obtained by the processing to a remote place via a channel 6090. This makes it possible to display the image on a display 6081 installed in a doctor room in another place, or record the image on a recording medium such as an optical disk. The recording medium may also be a film 6110. In this case, a film processor 6100 records the image on the film 6110.

The solid-state image sensing device according to the present invention is also applicable to an image sensing system for sensing an image of visible light. This image sensing system can include, for example, the solid-state image sensing device 100, and a processor for processing a signal output from the solid-state image sensing device 100. The processing performed by the processor can include at least one of, for example, an image format converting process, image compressing process, image size changing process, and image contrast changing process.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-129033, filed Jun. 19, 2013, and Japanese Patent Application No. 2013-129032, filed Jun. 19, 2013, which are hereby incorporated by reference herein in their entirety.

What is claimed is:

1. A method of manufacturing a radiation detection apparatus, the method comprising:
a bonding step of bonding, on a support substrate, a sensor substrate including a photoelectric converter in which a plurality of photoelectric conversion elements are arranged, by using a bonding layer including a passage which exhausts a gas between the support substrate and the sensor substrate; and
a formation step of forming a scintillator layer on the photoelectric converter after the bonding step,
wherein the bonding layer has a heat resistance by which bonding between the support substrate and the sensor substrate by the bonding layer is maintained in the formation step.

2. The method according to claim 1, wherein
the bonding step includes a first step of arranging the support substrate and the sensor substrate with a bonding material being sandwiched therebetween, and a second step of forming the bonding layer by curing the bonding material,
the formation step includes a step of forming the scintillator layer on the photoelectric converter by a vapor-deposition method, and
the bonding layer contains particles and an adhesive agent, and the particles are arranged such that a cavity for providing the passage is formed therebetween.

3. The method according to claim 2, wherein a volumetric filling factor of the particles in the bonding layer is not less than 40% and is not more than 80%.

4. The method according to claim 2, wherein a diameter of the particles is not less than 0.1 μm and is not more than 20 μm.

5. The method according to claim 2, wherein a value of (volume of all organic adhesive agents contained in bonding material)/((volume of all particles contained in bonding material)+(volume of all organic adhesive agents contained in bonding material)+(volume of all inorganic adhesive agents contained in bonding material)) is not less than 0.01% and is not more than 10%.

6. The method according to claim 1, wherein a thickness of the bonding layer is not less than 20 μm.

7. The method according to claim 2, wherein in the first step, the bonding material is arranged between the sensor substrate and the support substrate in a state in which the bonding material is dispersed in an organic solvent.

8. The method according to claim 2, wherein the particles are made of:
(a) a material selected from a group consisting of at least one material selected from the group consisting of a methyl polymethacrylate-based crosslinked material, a butyl polymethacrylate-based crosslinked material, a polyacrylic ester crosslinked material, a styrene-acrylic-based crosslinked material, a polyamidoimide resin, a polyphenylene sulfide resin, an epoxy resin, and a polyether sulfone resin, or
(b) at least one material selected from a group consisting of silica, alumina, cordierite, bentonite, zirconia, zircon, carbon, yttrium oxide, magnesia, titania, and chromium oxide, or
(c) a silica-acryl composite compound.

9. The method according to claim 2, wherein the adhesive agent is a material selected from a group consisting of an epoxy-based adhesive agent, an acrylic-based adhesive agent, a silicone-based adhesive agent, an alkali metal silicate-based adhesive agent, a phosphate-based adhesive agent, and a silica sol-based adhesive agent.

10. The method according to claim 1, wherein the sensor substrate is a semiconductor substrate on which the photoelectric converter is formed.

11. The method according to claim 10, wherein in the bonding step, a plurality of sensor substrates are bonded on the support substrate by the bonding layer.

12. A radiation detection apparatus comprising:
a support substrate;
a sensor substrate arranged on the support substrate, and including a photoelectric converter in which a plurality of photoelectric conversion elements are arranged;
a scintillator layer arranged on the photoelectric converter; and
a bonding layer including a passage which exhausts a gas between the support substrate and the sensor substrate, and configured to bond the support substrate and the sensor substrate,
wherein the bonding layer has a heat resistance by which bonding between the sensor substrate and the support substrate by the bonding layer is maintained against a temperature when the scintillator layer is arranged.

13. The apparatus according to claim 12, wherein
the scintillator layer is formed on the photoelectric converter by a vapor-deposition method, and
the bonding layer contains particles and an adhesive agent, and the particles are arranged such that a cavity for providing the passage is formed therebetween.

14. The apparatus according to claim 13, wherein a volumetric filling factor of the particles in the bonding layer is not less than 40% and is not more than 80%.

15. The apparatus according to claim 13, wherein a diameter of the particles is not less than 0.1 μm and is not more than 20 μm.

16. The apparatus according to claim 12, wherein the sensor substrate is a semiconductor substrate on which the photoelectric converter is formed.

17. The apparatus according to claim 12, wherein the scintillator layer is formed on the sensor substrate by a vapor-deposition method.

18. A radiation image sensing system comprising:
a radiation image sensing apparatus cited in claim 12; and
a processor configured to process a signal output from the radiation image sensing apparatus.

19. A method of manufacturing a radiation detection apparatus, the method comprising:
a bonding step of bonding, on a support substrate, a sensor substrate including a photoelectric converter in which a plurality of photoelectric conversion elements are arranged, by using a bonding layer; and
a formation step of forming a scintillator layer on the photoelectric converter after the bonding step,
wherein the bonding layer contains an inorganic adhesive agent having a heat resistance by which bonding between the support substrate and the sensor substrate by the bonding layer is maintained in the formation step.

20. The method according to claim 19, wherein a thermal expansion coefficient of the inorganic adhesive agent when it is cured is not more than 15×10⁻⁶ K⁻¹.

21. The method according to claim 19, wherein in the formation step, the scintillator layer is formed on the sensor substrate by a vapor-deposition method.

22. The method according to claim 19, wherein the inorganic adhesive agent is one of an alkali metal silicate-based adhesive agent, a phosphate-based adhesive agent, and a silica sol-based adhesive agent.

23. The method according to claim 19, wherein the inorganic adhesive agent contains inorganic particles.

24. The method according to claim 23, wherein the inorganic particles contain at least one type of particles selected from a group consisting of silica, alumina, cordierite, bentonite, zirconia, zircon, carbon, phosphoric acid, yttrium oxide, magnesia, titania, and chromium oxide.

25. The method according to claim 19, wherein the sensor substrate is a semiconductor substrate on which the photoelectric converter is formed.

26. The method according to claim 19, wherein in the bonding step, a plurality of sensor substrates are bonded on the support substrate by the bonding layer.
